(19) United States
(12) Patent Application Publication
(10) Pub. No.: US 2004/0130428 A1
(43) Pub. Date: Jul. 8, 2004

(54) Surface mount magnetic core winding structure

(76) Inventors: Peter Mignano, Austin, TX (US); Allan Mark, Nashua, NH (US); Hong Huang, North Andover, MA (US); Chris Young, Austin, TX (US)

Correspondence Address: COUDERT BROTHERS LLP, Two Palo Alto Square, 3000 El Camino Real, Fourth Floor, Palo Alto, CA, 94306, US

(21) Appl. No.: 10/697,856

(22) Filed: Oct. 29, 2003

Related U.S. Application Data
(60) Provisional application No. 60/422,917, filed on Oct. 31, 2002.

(51) Int. Cl. H01F 27/28

(52) U.S. Cl. 336/229

(57) ABSTRACT

A method and corresponding structure having conductors fastened in an offset fashion to appropriately patterned traces on the PCB to surround a single magnetic core positioned on the surface of the printed circuit board so as to create an inductor coil. The inventive method and structure reduces component and manufacturing cost by providing substantially pie-slice shaped conductors shaped for efficient automated production since the inventive shaped conductors can be soldered in place during the reflow process for the entire printed circuit board. As a result, a low profile surface mounted inductor is provided. Flux leakage is also reduced compared to known magnetic core winding structures.

### CROSS REFERENCE TO RELATED APPLICATION

This application claims the benefit of U.S. Provisional Application No. 60/422,917, filed Oct. 31, 2002, which is incorporated by reference herein.

### FIELD OF THE INVENTION

The present invention relates in general to surface mount inductors, and more particularly to a method and corresponding structure including conductors shaped to surround a magnetic core to form, in conjunction with traces on a PCB, the inductor's winding. The conductors are also shaped for efficient positioning and soldering on the PCB using automated equipment.

### BACKGROUND OF THE INVENTION

A typical magnetic core winding structure for an inductor typically includes a ferrite core that is wound with wire using a header or bobbin that holds both the wire and the core in the desired position. The trend in modem technology is towards higher density and lower profile electrical devices. A common disadvantage of known magnetic core winding structures and methods having a bobbin or header is that these structures have substantial height and are therefore not desirable for low profile applications such as for inductors mounted on a printed circuit board (PCB).

Known inductors include rectangular magnetic cores that have specially defined surface features for retaining the current conducting pieces that form the inductor's winding. These specially defined features result in a structure that is not easily assembled, thereby increasing manufacturing time and cost. For these known devices, the free flux from the core ends can pass through the copper traces of the PCB producing eddy current losses. This flux leakage also induces noise currents and electromagnetic interference (EMI) that can interfere with other signals on the PCB. In addition, two or more such rectangular core devices are typically used to form a magnetic circuit providing a return flux path, thereby increasing cost compared to devices requiring only a single core. Additionally, these known rectangular inductor structures have power handling limitations due to their open core design, winding structure, and core size limitations.

The above described surface features of rectangular cores are typically shaped so that the conductors can be pressed into grooves on the sides of the core. This limits the thickness of the conductor since a thick conductor would damage the core during the pressing process. The thin rectangular shape of such known inductors has the disadvantage that it causes bowing as the length increases.

Known prior art methods and structures for forming inductors also utilize toroidal cores, rather than rectangular cores, and conductive strips, rather than wires, for the windings. The conductive strips of these prior art structures have a substantially uniform cross-section and require the use of a lead frame. Such resulting prior art structure requires substantial post processing during manufacturing in order to remove the lead frame without causing damage to the remaining structure. As a result, these prior art structures and methods are costly due to the increased manufacturing time and complexity necessitated by the need to remove the lead frame. In addition, these known structures do not achieve the lowest resistance for a given toroid dimension.

A method and corresponding device are therefore needed that will enable use of a magnetic core winding in low profile applications while reducing flux leakage, component cost, and manufacturing cost by being suitable for automated PCB solder flow processes.

### SUMMARY OF THE INVENTION

The present invention solves the above described drawbacks of known devices and methods by providing a method for forming an inductor and a corresponding inductor structure comprising conductors shaped to surround a magnetic core to form, in conjunction with traces on a PCB, a winding on the core. In a preferred embodiment, the inventive inductor includes a toroidal core. The inventive structure is shaped to enable efficient insertion and soldering of the conductors on the PCB using standard automated equipment. In the inventive method and structure, conductors are fastened to appropriately patterned traces on the PCB to surround a single magnetic core positioned on the surface of the PCB. The inventive method and structure reduces component and manufacturing cost by providing substantially pie-slice shaped conductors that are shaped for efficient automatic positioning and to enable the conductors to be soldered in place during the reflow process for the entire printed circuit board. As a result, a low profile surface mounted structure is provided. Flux leakage is also reduced compared to known magnetic core winding structures.

The inventive method and corresponding structure according to the present invention includes conductors that can be custom designed for any core shape, size, and power rating. In an alternate embodiment, the conductors are preassembled to create a single unit for placing on a PCB using automated equipment.

The present invention includes conductors that can be placed on a PCB in a stable configuration using automatic insertion equipment. The conductors have an inventive shape having a cross section that varies substantially radially with respect to the toroid in order to provide more mechanical stability and to have the lowest resistance for a given toroid dimension. This increased stability results from the aspect ratio of the inventive shaped conductors being such that, once a conductor is placed on the PCB, it is not prone to tip over. Known prior art conductors lack such stability and as a result, must be formed into a lead frame. Without such a lead frame, the prior art conductors would not be stable in a production environment.

Another advantage of the present invention is that, unlike the prior art, the amount of magnetic core material that is visible between adjacent conductors is minimized. The inventive method and structure enables the conductors to be shaped so as to minimize the space between adjacent conductors, which provides the advantage of reduced flux leakage.

Another advantage of the present invention is that the resulting structure is substantially more rigid and allows the core to be captured by the conductors themselves, and therefore does not require adhesive to bond the core to the PCB as required for prior art methods.

An additional advantage of one embodiment of the present invention is that it provides for the preassembly of the conductors in a single potted unit which enables easy placement of the conductors on the PCB by automatic insertion equipment. The device and corresponding method of the present invention also makes use of distributed gap cores, such as powdered metal cores, that have the advantage of retaining most of the flux in the core.

An additional advantage of one embodiment of the present invention is the winding limitation of the known rectangular designs is avoided since, according to the present invention, the windings are fitted over the core so as to enable the availability of a much wider and thicker copper conductor, for carrying the required current.

The present invention also has the advantage of reducing inductor cost by requiring only a single core of a type widely available from a number of sources.

The present invention also has the advantage of not being limited in size as a result of the large aspect ratio of known rectangular designs.

Another advantage of the present invention is that the conductors are not pressed into grooves on the sides of the core like known rectangular inductor designs, and therefore the conductors are not limited in dimension or thickness on this basis. The conductors are limited by the PCB trace dimensions that the conductors connect to; however, thicker copper, multiple layers, or formed copper pieces can be used to supplement current carrying capacity of the PCB traces. The inventive structure and method enables the conductors to provide both an electrical conductor for the magnetic core and a way to fasten the core to a PCB.

Another advantage of the present invention is that it enables reduced height as compared to devices having a bobbin or header such that the present invention is particularly desirable for low profile applications.

Additional advantages of the present invention are that the present invention spreads the magnetizing field uniformly over the core, reduces AC losses created by a larger surface area; and spreads the heat energy over a larger surface area so as to enable a lower operating temperature and to provide a heat sink for the core.

Broadly stated, the present invention provides an inductor formed on a printed circuit board and a corresponding method, the inductor comprising a plurality of conductive traces on a surface of the printed circuit board; a single magnetic core positioned on the surface over the conductive traces; and a plurality of pie-slice shaped conductors positioned on the traces, wherein each of the plurality of pie-slice shaped conductors is fastened in offset fashion to a corresponding pair of the conductive traces to surround the core so as to create a coil.

### BRIEF DESCRIPTION OF THE DRAWINGS

The foregoing aspects and attendant advantages of the present invention will become more readily appreciated by reference to the following detailed description, when taken in conjunction with the accompanying drawings, wherein:

FIG. 1 is a perspective view of an embodiment of the surface mount magnetic core winding structure according to the present invention as attached to a printed circuit board;

FIG. 2 illustrates the traces on a surface of the printed circuit board according to a preferred embodiment of the present invention;

FIG. 3 illustrates a core positioned on the surface of the PCB over the traces shown in FIG. 2;

FIG. 4 illustrates an exemplary embodiment of the surface of a printed circuit board having traces thereon as shown in FIG. 2 according to the present invention;

FIG. 5 is a top view of an embodiment of the conductors according to the present invention;

FIG. 6 illustrates an upper perspective view of the conductor of FIG. 5;

FIG. 7 illustrates a side view of the conductor of FIG. 5;

FIG. 8 illustrates a side perspective view of the conductor of FIG. 5;

FIG. 9 is a perspective view of a partially assembled inductor according to an exemplary embodiment of the present invention, showing three conductors positioned around a core on a printed circuit board;

FIG. 10 is a perspective view of a fully assembled inductor according to an embodiment of the present invention illustrating the placement of the remaining three conductors around the core assembly shown in FIG. 9;

FIG. 11 is a top perspective view of the method and corresponding structure according to an alternative embodiment of the present invention wherein the conductors are preassembled as a single unit preferably using a non-conductive potting compound for automated placement on the PCB; and

FIG. 12 is a bottom perspective view of the embodiment of FIG. 11.

Reference symbols are used in the Figures to indicate certain components, aspects or features shown therein, with reference symbols common to more than one Figure indicating like components, aspects or features shown therein.

### DETAILED DESCRIPTION OF THE INVENTION

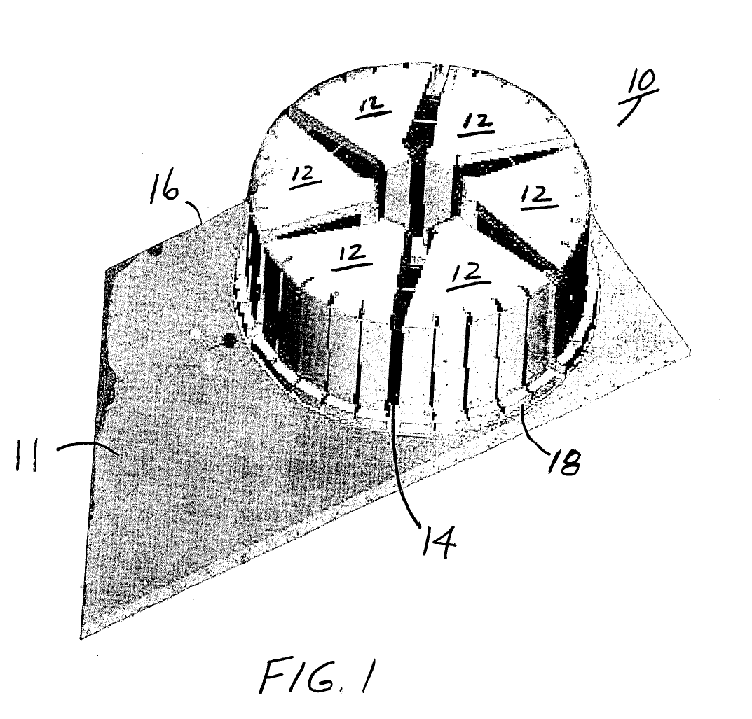

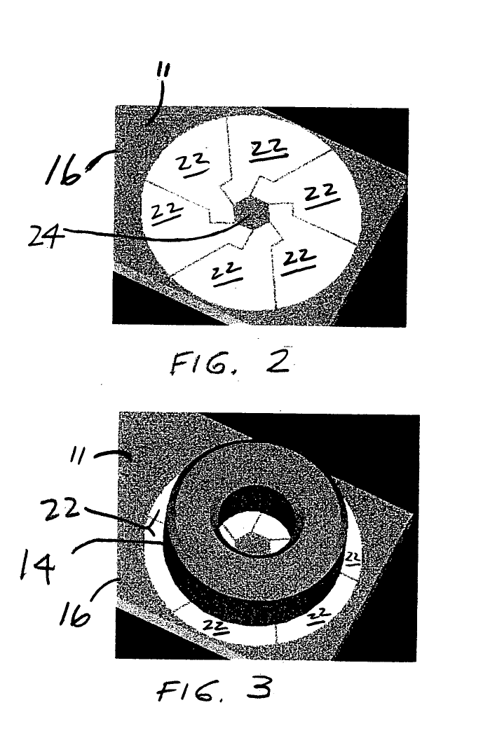

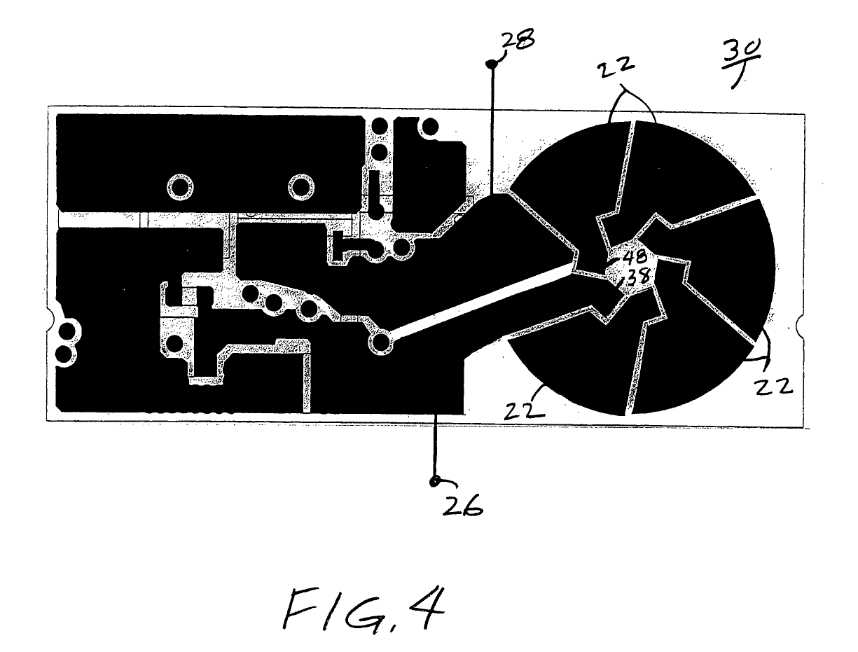

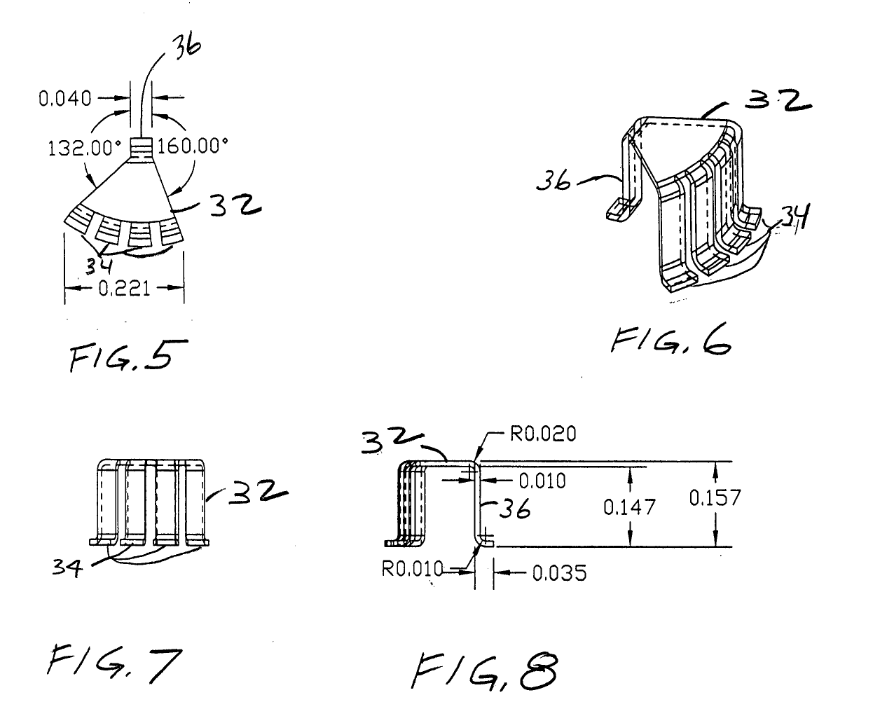

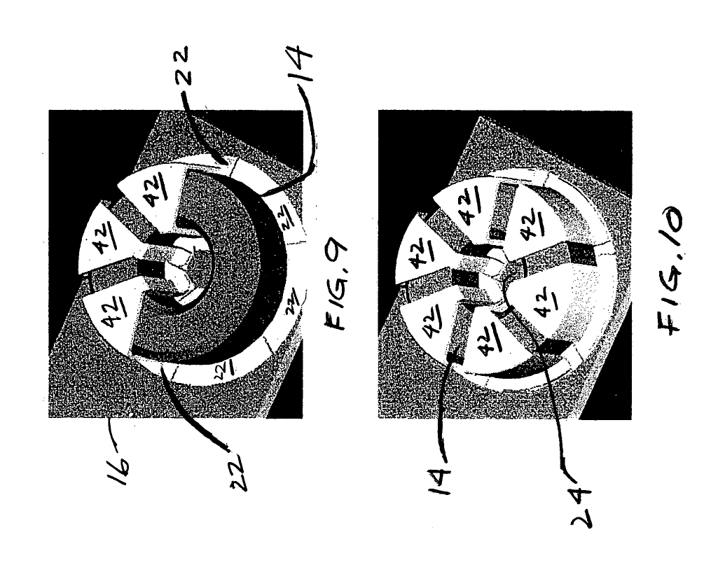

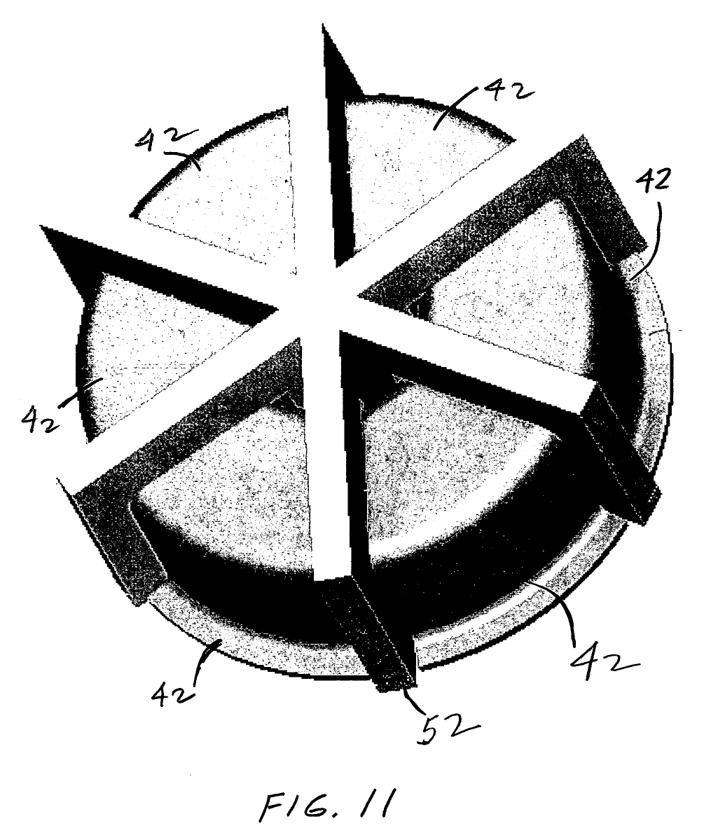

The present invention will now be described in more detail with reference to the Figures. FIG. 1 is a perspective view of an embodiment of the assembly 10 according to the present invention formed on the surface 11 of a printed circuit board 16, or the like. As shown in FIG. 1, the assembly 10 has a surface mount magnetic core winding structure 18 attached to surface 11. Structure 18 has a plurality of substantially pie-slice shaped conductors 12 surrounding a core 14. The conductors 12 form the top half turn of a full turn of a coil winding, while traces on surface 11 (shown in FIG. 2) form the bottom half of each turn. One pie-slice shaped conductor 12 is used for each winding loop.

FIG. 2 illustrates the printed circuit board traces according to a preferred embodiment of the present invention, prior to the surface mounting of the winding structure 18 thereon. As shown in FIG. 2, the printed circuit board 16 has a surface 11 having a plurality of traces 22 thereon. As also shown in FIG. 2, the traces 22 each have an offset near the center 24 such that a coil effect of interconnected windings is created when the structure 18 is positioned thereon. In an alternate embodiment of the present invention, the same effect is achieved by forming the offset as part of the structure 18. In this embodiment, the traces 22 on surface 11 of PCB 16 are not offset. FIG. 3 illustrates the core 14 positioned on the surface 11 of PCB 16 over the traces 22 shown in FIG. 2. The core 14 is preferably a toroidal core composed of a ferrite material. However; any suitably shaped core may be used. Alternately, core 14 may be composed of a non-ferrite material, in which case a suitable dielectric coating is used to insulate the core from the traces 22.

FIG. 4 illustrates an exemplary embodiment 30 of the component side of an exemplary PCB 16 including offset traces 22 shown in FIG. 2. FIG. 4 illustrates terminals formed to enable connection of the ends of the coil, formed using the present invention, to the rest of the circuit on PCB 16. FIG. 4 shows a one trace 22 separated electrically into two portions in order to provide terminals 26 and 28 (shown schematically in FIG. 4). In this exemplary embodiment 30, one of the plurality of conductors is placed to connect between an offset center pad 38 and the adjacent trace 22 (shown below pad 38 in FIG. 4) to form one end of the coil which is connected to terminal 26. A separate conductor is placed such that a connection is made between terminal 28 and an offset center pad 48 to form the other end of the coil. Terminals 26 and 28 thus provide a path to enable connection of the coil, formed using the present invention, to the rest of the circuit on PCB 16. Alternately, one of ordinary skill in the art would recognize that a tapped inductor (autotransformer) may be formed using the present invention by simply making another electrical connection on one of the other turns, thereby forming a three terminal device. Furthermore, one of ordinary skill in the art would recognize that a transformer may be realized using the present invention by having one or more additional breaks in the windings and appropriate electrical connections on the turns.

FIGS. 5-8 illustrate views of an exemplary embodiment 32 according to the present invention of the substantially pie-slice shaped conductors 12 shown in FIG. All measurements shown are merely exemplary; the present invention is not limited to the specific dimensions shown. The conductors are composed of a conductive material, preferably copper. FIG. 5 is a top view of an embodiment of the substantially pie-slice shaped conductor piece 32 according to the present invention. FIG. 6 illustrates an upper perspective view of the conductor 32 of FIG. 5. FIG. 7 illustrates a side view of the conductor 32 of FIG. 5. FIG. 8 illustrates a side perspective view of the conductor 32 of FIG. 5. The conductors have a cross section that varies substantially radially with respect to the toroidal core over which they are mounted. The inventive conductor shape has several advantages including that of providing more copper than known methods, thereby providing less resistance, and reducing flux leakage and EMI interference for the PCB.

As shown in FIGS. 1 and 5-8, each conductor 12, 32 comprises a pie-slice shaped portion having fingers 34 extending down preferably in a perpendicular direction from the plane of the pie-slice shaped portion. As is seen, these fingers 34 extend down from the arc-shaped circumference (periphery) of the pie-shaped portion. A separate finger 36 extends in the same direction from the opposite side of the pie-shaped portion. For the conductor 12 shown in FIG. 1, there are five fingers 34 extending from the arc-shaped circumference. The number of fingers is a matter of design choice. The arc-shaped circumference of the pie-slice shaped portion of conductor 32 shown in FIGS. 5-8, has four fingers 34 extending therefrom.

The use of a plurality of fingers 34 extending down from the arc-shaped circumference of the conductor are necessitated by some machining methods to avoid buckling of the conductor material. In an alternative embodiment, the portion of the conductor that extends down from the plane of the pie-shaped portion can be a solid piece, i.e., without separate fingers 34, where the conductor is manufactured by some method other than the bending of a copper sheet.

FIGS. 9-12 show conductors 42 according to a preferred embodiment of the present invention. FIG. 9 is a perspective view of a partially assembled inductor according to an exemplary embodiment of the present invention, showing three such conductors 42 positioned around a core on a printed circuit board.

FIG. 10 is a perspective view of a fully assembled inductor according to an embodiment of the present invention illustrating the placement of the remaining three conductors around the core assembly shown in FIG. 9. As can be seen, each conductor provides a segment of a loop of the winding formed around toroidal core 14.

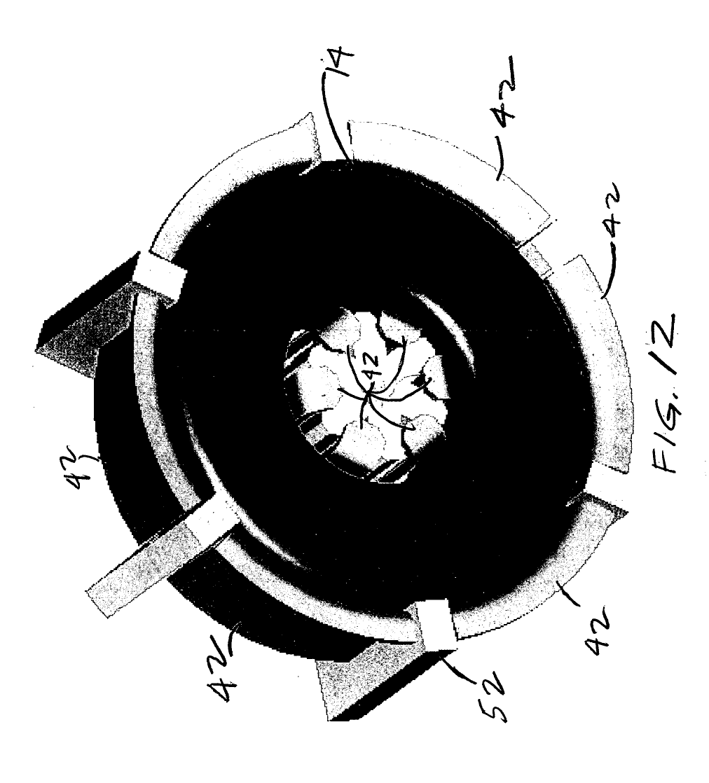

The pie-slice shape of the conductors according to the present invention has the advantage of enabling efficient “pick and place” insertion and soldering of the conductors on the PCB using standard automated equipment. For one embodiment of the present invention each individual conductor piece is separately placed to surround the core. FIG. 11 is a top perspective view of the method and corresponding structure according to an alternative embodiment of the present invention wherein the conductors 42 are preassembled as a single unit, preferably using a non-conductive potting compound, for automated placement on the PCB. FIG. 12 is a bottom perspective view of the embodiment of FIG. 11.

As shown in FIG. 11, a potting assembly 52 is provided to enable preassembling of the conductors as a single unit. FIG. 12 illustrates the core 14 being surrounded by the pie-slice shaped conductors 42 in the potting assembly 52 prior to automated placement on a printed circuit board.

The foregoing detailed description of the invention has been provided for the purposes of illustration and description. Although exemplary embodiments of the present invention have been described in detail herein with reference to the accompanying drawings, it is to be understood that the invention is not limited to the precise embodiments disclosed, and that various changes and modifications to the present invention are possible in light of the above teaching and appended claims.

What is claimed is:

1. An inductor formed on a printed circuit board comprising:
a plurality of conductive traces on a surface of said printed circuit board;
a single magnetic core positioned on said surface over said conductive traces; and
a plurality of pie-slice shaped conductors positioned on said traces, wherein each of said plurality of pie-slice shaped conductors is fastened in offset fashion to a corresponding pair of said conductive traces to surround said core so as to create a coil.

2. The inductor of claim 1, wherein said magnetic core is a toroidal core.

3. The inductor of claim 2, wherein said toroidal core is composed of a ferrite material.

4. The inductor of claim 1, wherein said core is composed of a non-ferrite material, said inductor further comprising a dielectric coating for said core to insulate said core from said conductive traces.

5. The inductor of claim 1, wherein said plurality of pie-slice shaped conductors comprises six conductors.

6. The inductor of claim 1, wherein each said pie-slice shaped conductor comprises a pie-slice shaped portion and a plurality of fingers extending downwardly from the plane of said pie-slice shaped portion, each said finger shaped to contact one of said conductive traces.

7. The inductor of claim 6, wherein said plurality of fingers comprises five fingers.

8. The inductor of claim 6, wherein said pie-slice shaped portion includes an arc-shaped circumference end and another end, said pie-slice shaped portion being broadest at the arc-shaped circumference end, each said pie-slice shaped conductor having each of said fingers extending downwardly in a perpendicular direction from the plane defined by said pie-slice shaped portion.

9. The inductor of claim 8, wherein a single finger extends downwardly in a perpendicular direction from said circumference end of said pie-sliced shaped portion.

10. The inductor of claim 1, wherein each said conductor forms a top half turn of a full turn of a winding loop of said coil and each corresponding conductive trace forms a bottom half turn of each corresponding full turn, such that each said pie-slice shaped conductor is used for each said winding loop of said coil.

11. The inductor of claim 1, wherein said conductive traces converge at a center portion and each said conductive trace has an offset near said center portion so as to enable each said conductor to be fastened in offset fashion to a corresponding pair of conductive traces.

12. The inductor of claim 1, wherein an offset is formed from each said conductor so as to enable each said conductor to be fastened in offset fashion to a corresponding pair of said conductive traces.

13. The inductor of claim 1, wherein said printed circuit board comprises a plurality of additional circuit traces on said surface for enabling connection to components mounted thereon and a plurality of terminals formed thereon to enable connection of a first end and a second end of said coil to said components.

14. The inductor of claim 10, wherein a separate electrical connection is made on one of said full turns so as to form a three terminal device, thereby enabling operation of said inductor as a tapped inductor.

15. The inductor of claim 10, wherein said inductor includes one or more breaks in said winding loop so as to enable electrical connection to be made to said turns to enable operation of said inductor as a transformer.

16. The inductor of claim 1, wherein said conductors are preassembled as a single unit using a non-conductive potting compound prior to placement on said printed circuit board using automated equipment.

17. The inductor of claim 1, wherein said conductors are preassembled as a single unit using a potting assembly, said core being surrounded by said conductors in said potting assembly prior to automated placement on said printed circuit board.

18. A method for forming an inductor on a printed circuit board having a plurality of conductive traces on a surface thereof, comprising the steps of:
positioning a single magnetic core on said surface over said conductive traces;
positioning a plurality of pie-slice shaped conductors on said traces, and
fastening each of said plurality of pie-slice shaped conductors in offset fashion to a corresponding pair of said conductive traces to surround said core so as to create a coil.

19. The method of claim 18, further comprising the step of preassembling said conductors as a single unit before said positioning of said conductors on said traces.

20. The method of claim 19, wherein a non-conductive potting compound is used for said preassembling step.

21. The method of claim 20, including the steps of providing a potting assembly, preassembling said conductors as a single unit into said potting assembly, positioning said core into said potting assembly such that said conductors surround said core, and positioning said potting assembly containing said conductors and said core onto said printed circuit board using automated equipment.

22. The method of claim 20, wherein said fastening step further comprises soldering said conductors in place on said printed circuit board during a reflow process for the entirety of said printed circuit board.

23. The method of claim 18, wherein said fastening step includes forming a top half turn of a full turn of a winding loop of said coil from each said conductor and forming a bottom half turn of each corresponding full turn from each corresponding conductive trace such that each said pie-slice shaped conductor is used for each said winding loop of said coil.

24. The method of claim 18, wherein each said pie-slice shaped conductor comprises a pie-slice shaped portion and a plurality of fingers extending downwardly from the plane of said pie-slice shaped portion, each said finger shaped to contact one of said conductive traces.

25. The method of claim 18, wherein said printed circuit board further includes a plurality of circuitry traces on said surface for enabling electrical connection to circuitry mounted thereon, further comprising the step of forming a first and second terminal on said printed circuit board to enable connection of a first end and a second end of said coil to said circuitry.

26. The method of claim 25, further comprising the steps of:
separating one of said conductive traces into first and second portions wherein said first portion is electrically isolated from said second portion;
connecting said first terminal to said first portion and said second terminal to said second portion;
placing one of said conductors to connect between a first offset center pad and said conductive trace adjacent to said first separated portion to form one end of said coil connected to said first terminal; and
placing another of said conductors to connect between a second offset center pad and said conductive trace adjacent to said second separated portion to form the other end of said coil connected to said second terminal such that said first and second terminals provide a path to enable connection of said coil to said circuitry on said printed circuit board.
